(19) United States
(12) Patent Application Publication
(10) Pub. No.: US 2025/0357359 A1
(43) Pub. Date: Nov. 20, 2025

(54) SEMICONDUCTOR MEMORY DEVICE AND METHOD OF MANUFACTURING SAME

(71) Applicant: Samsung Electronics Co., Ltd., Suwon-si (KR)

(72) Inventors: Wooyong JEON, Suwon-si (KR); Jonghun YU, Suwon-si (KR); Joowon PARK, Suwon-si (KR); Chang-Sup LEE, Suwon-si (KR); Kil-Su JEONG, Suwon-si (KR)

(21) Appl. No.: 18/958,027

(22) Filed: Nov. 25, 2024

(30) Foreign Application Priority Data
May 20, 2024 (KR) 10-2024-0065421

(51) Int. Cl. H01L 23/544; H01L 23/00; H01L 25/065; H01L 25/18; H10B 43/10; H10B 43/27; H10B 80/00

(52) U.S. Cl. CPC H01L 23/544; H01L 24/08; H01L 25/0657; H01L 25/18; H10B 43/10; H10B 43/27; H10B 80/00; H01L 2223/5446; H01L 2224/08145; H01L 2924/1431; H01L 2924/14511

(57) ABSTRACT

A method of manufacturing a semiconductor memory device with improved electrical characteristics and reliability includes providing a substrate including a first chip region, and a scribe lane region surrounding the first chip region, providing a mold including a plurality of mold insulating layers and a plurality of gate electrodes alternately stacked on the substrate in a first direction perpendicular to the substrate, providing a channel extending through the mold in the first direction, and providing a plurality of word line contacts extending through at least a portion of the mold in the first direction, in which the scribe lane region includes a scribe lane trench in the mold, a first insulating layer covering a bottom surface and a sidewall of the scribe lane trench, and a second insulating layer on the first insulating layer and filling the scribe lane trench, in which the substrate includes chip regions other than the first chip region and the method further comprises separating along the scribe lane region the first chip region from the other chip regions.

### CROSS-REFERENCE TO RELATED APPLICATION

This U.S. non-provisional application claims priority to Korean Patent Application No. 10-2024-0065421, filed in the Korean Intellectual Property Office on May 20, 2024, the entire contents of which are hereby incorporated by reference.

### BACKGROUND

### Field

The present disclosure relates to a semiconductor memory device and a method of manufacturing the same.

### Description of Related Art

There is a need for a semiconductor memory device capable of storing high-capacity data in an electronic system that requires data storage. Accordingly, ways to increase the data storage capacity of semiconductor memory devices are being studied. For example, as one of the methods for increasing the data storage capacity of the semiconductor device, a semiconductor device has been proposed, which includes a three-dimensional arrangement of memory cells instead of a two-dimensional arrangement of memory cells.

### SUMMARY

To solve one or more problems (e.g., the problems described above and/or other problems not explicitly described herein), the present disclosure provides a semiconductor memory device and an electronic system with improved electrical characteristics and reliability. Also provided are improved methods of manufacturing a semiconductor memory device.

According to some aspects, a method of manufacturing a semiconductor memory device may include a providing a substrate including a first chip region, and a scribe lane region surrounding the first chip region, providing a mold including a plurality of mold insulating layers and a plurality of gate electrodes which are alternately stacked on each other on the substrate in a first direction perpendicular to the substrate, providing a channel extending through the mold in the first direction, and providing a plurality of word line contacts extending through at least a portion of the mold in the first direction, in which the scribe lane region may include a scribe lane trench in the mold, a first insulating layer covering a bottom surface and a sidewall of the scribe lane trench, and a second insulating layer on the first insulating layer and filling the scribe lane trench. The substrate includes chip regions other than the first chip region and the method further includes separating along the scribe lane region the first chip region from the other chip regions.

According to some aspects, a method of manufacturing a semiconductor memory device may include providing a substrate including a first chip region including a cell array region and an extended region, and a scribe lane region surrounding the first chip region, providing a mold including a plurality of mold insulating layers and a plurality of gate electrodes which are alternately stacked on each other on the substrate in a first direction; providing a channel in the cell array region extending through the mold in the first direction, providing a plurality of word line contacts in the extended region, in which the plurality of word line contacts may extend through at least a portion of the mold in the first direction, and providing an insulative support disposed around each word line contact of the plurality of word line contacts in the extended region and extending through at least a portion of the mold in the first direction, in which the plurality of word line contacts may include word line contacts extending through one or more gate electrode of the plurality of gate electrodes, and the scribe lane region may include a scribe lane trench in the mold, a first insulating layer covering a bottom surface and a sidewall of the scribe lane trench, and a second insulating layer on the first insulating layer and filling the scribe lane trench. The substrate includes chip regions other than the first chip region and the method further includes separating along the scribe lane region the first chip region from the other chip regions.

According to some aspects, a method of manufacturing a semiconductor memory device may include alternately stacking a plurality of mold insulating layers and a plurality of mold sacrificial layers on a substrate in a first direction to form a pre-mold structure, in which the substrate may include a chip region including a cell array region and an extended region, and a scribe lane region surrounding the chip region, forming a plurality of word line contact holes in the extended region, in which the plurality of word line contact holes may extend through at least a portion of the pre-mold structure in first direction, forming a scribe lane trench on the pre-mold structure in the scribe lane region, and forming a sacrificial layer in the plurality of word line contact holes and on a bottom surface and a sidewall of the scribe lane trench, in which the plurality of word line contact holes and the scribe lane trench may be formed concurrently.

Also provided are semiconductor memory devices made by the methods provided herein.

According to some aspects, it is possible to form the holes in the chip region (e.g., the channel hole and the word line contact hole) and the trench in the scribe lane region concurrently, thus simplifying the semiconductor memory manufacturing processes.

According to some aspects, because the holes in the chip region (e.g., the channel holes and the word line contact holes) and the scribe lane trenches in the scribe lane region are formed concurrently, the proportion of the sacrificial layer patterns in the total volume increases when forming the scribe lane trench, and it is thus possible to prevent the warpage and crack of the stack. Accordingly, the reliability of the semiconductor memory device can be improved.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a schematic plan view of a semiconductor memory device according to some aspects;

FIG. 2 is a schematic plan view of the chip region in FIG. 1;

FIG. 3 is a cross-sectional view taken along line A-A of FIG. 2;

FIG. 4 is a cross-sectional view taken along line B-B of FIG. 2;

FIG. 5 is an enlarged view provided to depict a region Q1 of FIG. 6;

FIG. 6 is a schematic plan view of the scribe lane region of FIG. 1;

FIG. 7 is a cross-sectional view taken along line C-C of FIG. 6;

FIG. 8 is an enlarged view provided to depict the region Q2 of FIG. 7;

FIG. 9 is a diagram provided to depict a scribe lane region according to some aspects;

FIG. 10 is a diagram provided to depict a scribe lane region according to some aspects;

FIGS. 11 to 13 are diagrams showing intermediate stages, provided to depict a method of manufacturing a semiconductor memory device according to some aspects;

FIG. 14 is a diagram provided to depict a semiconductor memory device according to some aspects;

FIG. 15 is a diagram provided to depict a semiconductor memory device according to some aspects;

FIG. 16 is a diagram provided to depict a semiconductor memory device according to some aspects;

FIGS. 17 to 19 are diagrams showing intermediate stages, provided to depict a method for manufacturing a semiconductor memory device according to some aspects;

FIG. 20 is a block diagram provided as an example to depict an electronic system according to some aspects;

FIG. 21 is an example perspective view illustrating an electronic system including a semiconductor memory device according to some aspects; and

FIG. 22 is a schematic cross-sectional view taken along line V-V of FIG. 21.

### DETAILED DESCRIPTION

A semiconductor memory device, an electronic system including a semiconductor memory device, and a method of manufacturing the same according to some aspects will be described in detail with reference to drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” to, “adjacent” to, or “on” another element, it can be directly connected to or on the other element or intervening elements may be present. In contrast, when an element is referred to as being “directly connected” to another element, or as “contacting” or “in contact with” another element (or using any form of the word “contact” in its verb form), there are no intervening elements present at the point of contact.

Spatially relative terms, such as “upper,” “lower” and the like, may be used herein for ease of description to describe positional relationships, such as illustrated in the figures, for example. It will be understood that the spatially relative terms encompass different orientations of the device in addition to the orientation depicted in the figures.

It will be understood that, although the terms first, second, third, fourth, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention.

As used herein, the words “surround”, “surrounding” and “surrounded” are intended to mean that an element is around the other element. The elements may be touching or not. A first surrounding element may or may not completely surround a second element. For example, the second element may be surrounded around multiple sides of the second element, and may not be surrounded on the top and/or bottom of the second element.

It will be understood that the terms “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

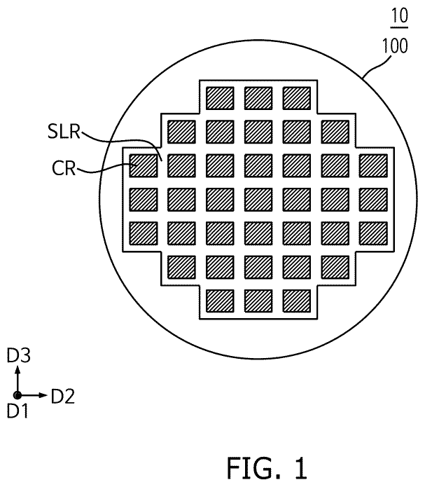

In the illustrations in FIGS. 1 to 22, a first direction D1, a second direction D2, and a third direction D3 are perpendicular to one another, and the first direction D1 and the second direction D2 form a plane, the second direction D2 and the third direction D3 form a plane, and the first direction D1 and the third direction D3 form a plane.

FIG. 1 is a schematic plan view of a semiconductor memory device 10 according to some aspects. The semiconductor memory device 10 may be a semiconductor chip (i.e., a semiconductor device singulated from (e.g., cut from) a wafer).

Referring to FIG. 1, the semiconductor memory device 10 may include a cell substrate 100 including a plurality of chip regions CR and a scribe lane region SLR surrounding the chip regions CR.

The plurality of chip regions CR may be repeatedly arranged and spaced apart from each other in the second direction D2 parallel to the cell substrate 100 or in the third direction D3 perpendicular to the second direction D2. Each chip region CR of the plurality of chip regions CR may be surrounded by a scribe lane region SLR. In addition, the scribe lane region SLR may be disposed between the plurality of chip regions CR and extend in the second direction D2 or the third direction D3.

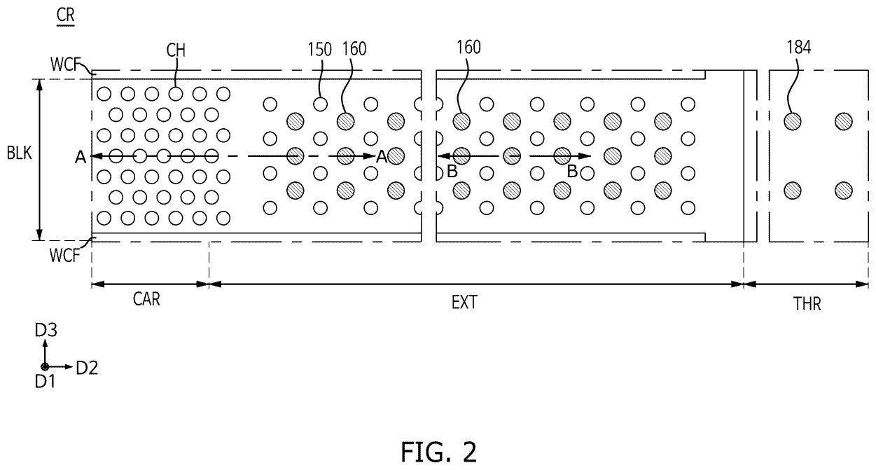

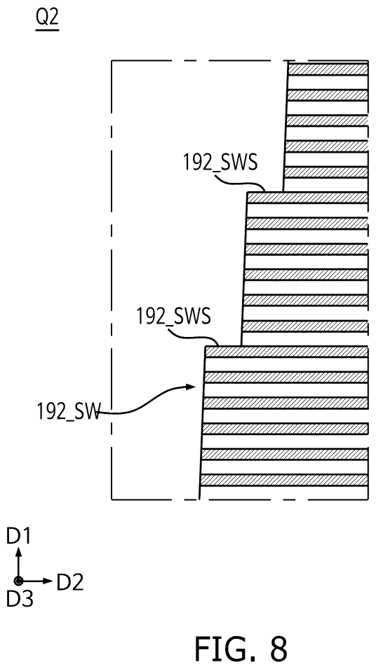

Details of the components disposed on the chip region CR will be described herein in detail with reference to FIGS. 2 to 5. In addition, details of the components disposed on the scribe lane region SLR will be described in detail with reference to FIGS. 8 to 10.

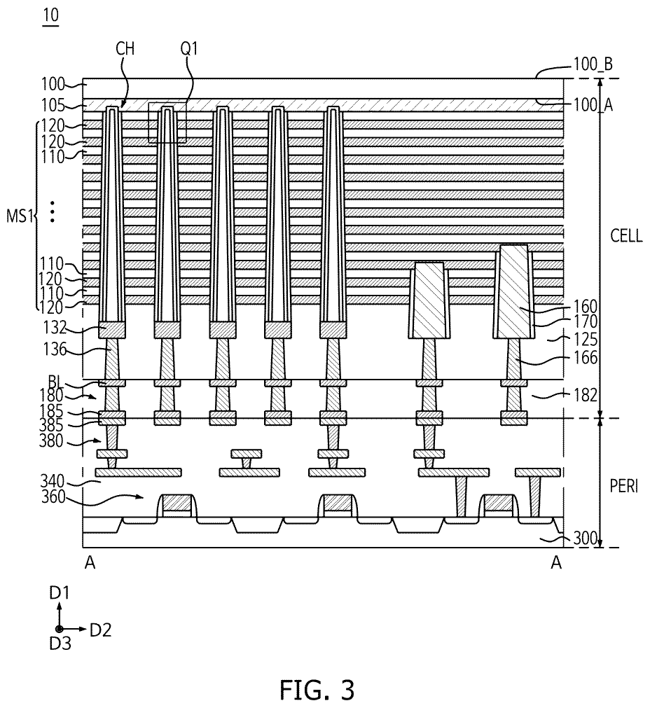

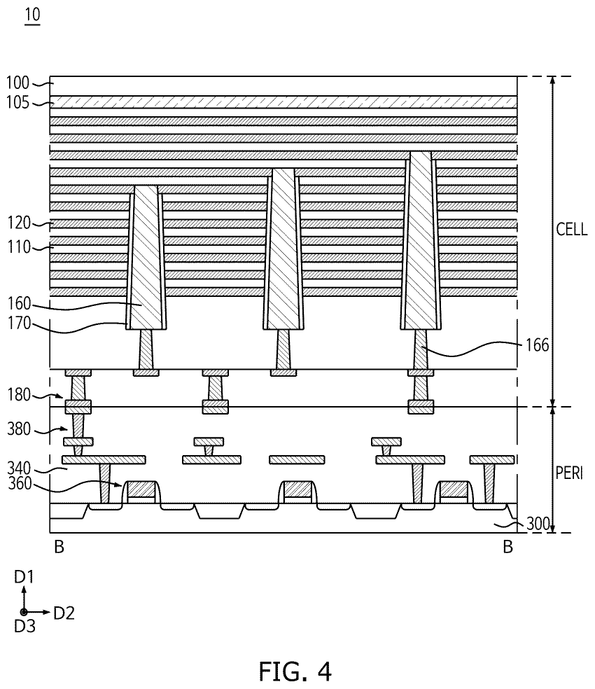

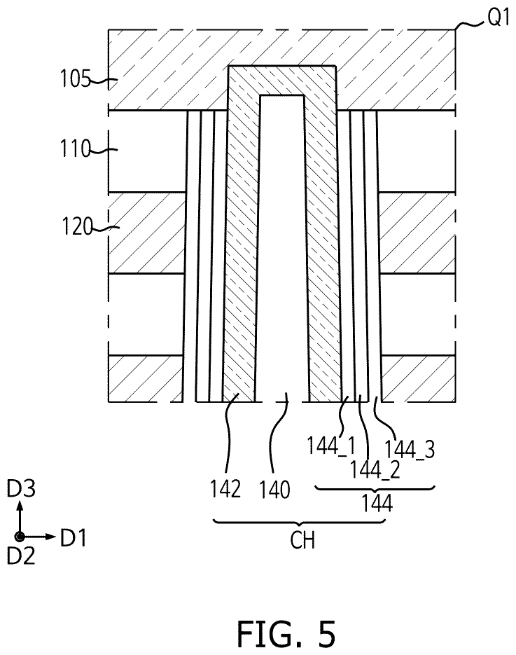

FIG. 2 is a schematic plan view of the chip region CR of FIG. 1. FIG. 3 is a cross-sectional view taken along line A-A of FIG. 2. FIG. 4 is a cross-sectional view taken along line B-B of FIG. 2. FIG. 5 is an enlarged view provided to depict the region Q1 of FIG. 3.

The plurality of chip regions CR may include a cell structure CELL and a peripheral circuit structure PERI.

The cell structure CELL may include the cell substrate 100, a common source plate 105, a first mold structure (also referred to herein as a “first mold”) MS1, a channel structure (also referred to herein as a “channel”) CH, a bit line BL, a word line contact 160, a contact spacer 170, a cell wiring structure 180, etc.

The cell substrate 100 may include a cell array region CAR, an extended region EXT, and a through region THR.

A memory cell array including a plurality of memory cells may be formed on the cell array region CAR. The channel structure CH, the first mold structure MS1, the bit line BL, etc. may be disposed on the cell array region CAR. In the present disclosure, the expression “a configuration B is formed (or disposed) on a configuration A” is not limited to the configuration B being formed or disposed in contact with the configuration A. For example, it may also include an aspect in which another configuration C is interposed between the configuration B and the configuration A. In addition, in the disclosure, the expression that “the configuration B is formed or disposed on the configuration A” is not limited to the configuration B being disposed above the configuration A in the drawings. For example, it may also include an aspect in which the configuration B is disposed under, or to the right or left side of the configuration A in the drawing.

The extended region EXT may be disposed in a peripheral region of the cell array region CAR. For example, the extended region EXT may surround the cell array region CAR. The word line contact 160, the contact spacer 170, a support structure (also referred to herein as a “support” or “insulative support”) 150, etc. may be disposed on the extended region EXT.

The through region THR may be disposed outside the extended region EXT. For example, the through region THR may be disposed on one side of the extended region EXT, but aspects are not limited thereto. A source contact 184, an input and output contact, etc. may be disposed in the through region THR.

For example, the cell substrate 100 may be a semiconductor substrate such as a silicon substrate, a germanium substrate, or a silicon-germanium substrate. Alternatively, the cell substrate 100 may be a silicon-on-insulator (SOI) substrate or a germanium-on-insulator (GOI) substrate, etc. In some aspects, the cell substrate 100 may include or may be polysilicon (poly Si).

The cell substrate 100 may include a first surface 100_A and a second surface 100_B opposite the first surface 100_A. The first surface 100_A of the cell substrate 100 may be a surface on which the first mold structure MS1 and the channel structure CH are disposed. The first surface 100_A of the cell substrate 100 may be referred to as a front side of the cell substrate 100. The second surface 100_B of the cell substrate 100 may be referred to as a back side of the cell substrate 100.

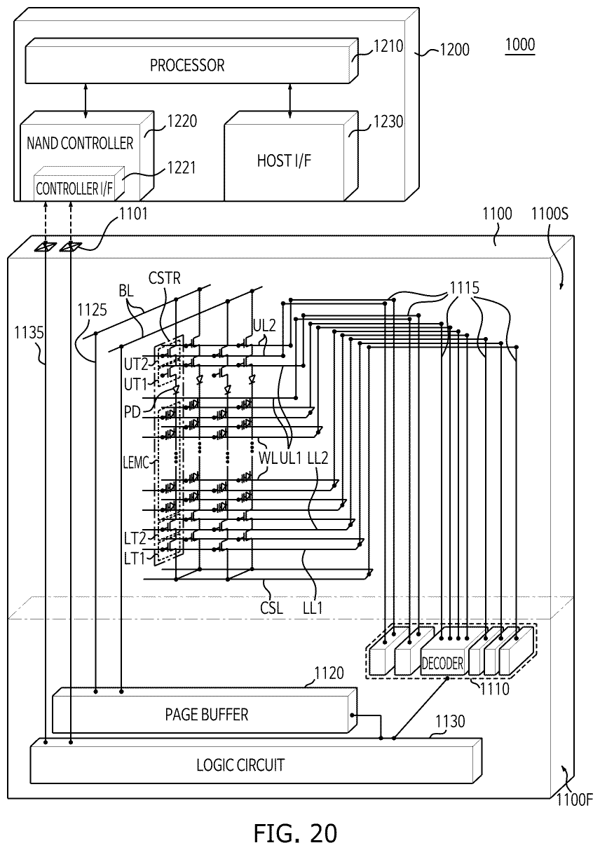

The common source plate 105 may be disposed on the first surface 100_A of the cell substrate 100. The common source plate 105 may be disposed on the cell array region CAR, the extended region EXT, and the through region THR. The common source plate 105 may be connected to the channel structure CH. For example, the common source plate 105 may be electrically connected to a semiconductor pattern 142 of the channel structure CH. The common source plate 105 may be connected to the source contact 184 in the through region THR. The common source plate 105 may be a common source line (e.g., a CSL of FIG. 20) of the semiconductor memory device. For example, the common source plate 105 may be polycrystalline silicon or metal doped with impurities, but aspects are not limited thereto.

The first mold structure MS1 may be disposed on the common source plate 105. The first mold structure MS1 may be disposed on the cell array region CAR and the extended region EXT of the cell substrate 100. The first mold structure MS1 may include a plurality of mold insulating layers 110 and a plurality of gate electrodes 120 alternately stacked in a third direction D3. Each of the mold insulating layers 110 and each of the gate electrodes 120 may be layered extending parallel to the first surface 100_A of the cell substrate 100. The gate electrodes 120 may be stacked in order on the common source plate 105 and spaced apart from each other by the mold insulating layers 110 therebetween.

In some aspects, some of the plurality of gate electrodes 120 may be a ground selection line GSL of a semiconductor memory device. The other gate electrodes 120 of the plurality of gate electrodes 120 may be a string select line SSL of the semiconductor memory device. For example, a gate electrode 120 adjacent to the common source plate 105, of the plurality of gate electrodes 120, may be the ground selection line GSL. The gate electrode 120 adjacent to the bit line BL, of the plurality of gate electrodes 120, may be the string select line SSL. However, aspects are not limited to the above. The arrangement and number of the ground selection lines GSL and the string select lines SSL may vary.

The mold insulating layer 110 may include an insulating material. For example, the mold insulating layer 110 may include at least one of silicon oxide, silicon nitride, or silicon oxynitride, but aspects are not limited thereto.

The gate electrode 120 may include or may be a conductive material. For example, the gate electrode 120 may include or may be a metal such as tungsten (W), cobalt (Co), nickel (Ni), or a semiconductor material such as silicon, but aspects are not limited thereto.

An interlayer insulating film 125 may be formed on the first surface 100_A of the cell substrate 100. The interlayer insulating film 125 may be disposed on the first mold structure MS1 to cover the first mold structure MS1. For example, the interlayer insulating film 125 may include or may be at least one of silicon oxide, silicon oxynitride, or a low-k material having a dielectric constant lower than that of silicon oxide, but aspects are not limited thereto.

The channel structure CH may be disposed on the cell array region CAR of the cell substrate 100. The channel structure CH may extend in the first direction D1, for example, in a direction perpendicular to the first surface 100_A of the cell substrate 100. The channel structure CH may extend through the first mold structure MS1. For example, the channel structure CH may extend through and intersect each gate electrode of the plurality of gate electrodes 120. The channel structure CH may have a pillar shape (e.g., a cylindrical shape) extending in the first direction D1. In some aspects, the cross section of the channel structure CH may have an inclined side surface such that its width is progressively narrowed toward the cell substrate 100. However, aspects are not limited to the above.

As illustrated in FIG. 5, the channel structure CH may include a filling insulating film 140, the semiconductor pattern 142, and an information storage film 144.

The semiconductor pattern 142 may extend in the third direction D3 and through the mold structure (also referred to herein as the “mold”) MS. Although the illustrated semiconductor pattern 142 has a cup shape, aspects are not limited thereto. The semiconductor pattern 142 may have various shapes such as a cylindrical shape, a rectangular cylindrical shape, a filled filler shape, etc. For example, the semiconductor pattern 142 may include or may be a semiconductor material such as a single crystal silicon, a polycrystalline silicon, an organic semiconductor material, or a carbon nanostructure, etc., although aspects are not limited thereto.

The information storage film 144 may be interposed between the semiconductor pattern 142 and each of the gate electrodes 120. For example, the information storage film 144 may extend along an outer surface of the semiconductor pattern 142. For example, the information storage film 144 may include or may be at least one of silicon oxide, silicon nitride, silicon oxynitride, or a high-k material having a higher dielectric constant than silicon oxide. For example, the high-k material may include or may be at least one of aluminum oxide, hafnium oxide, lanthanum oxide, tantalum oxide, titanium oxide, lanthanum hafnium oxide, lanthanum aluminum oxide, or dysprosium scandium oxide, or a combination thereof.

In some aspects, the channel structures CH may be disposed in a zigzag form. For example, as illustrated in FIG. 2, the channel structures CH may be arranged to cross with one another in the second direction D2 and the third direction D3. The channel structures CH disposed in the zigzag form may further improve the degree of integration of the semiconductor memory device. In some aspects, the channel structures CH may be disposed in a honeycomb form.

In some aspects, the information storage film 144 may include multiple layers. The information storage film 144 may include a tunnel insulating film 144_1, a charge storage film 144_2, and a blocking insulating film 144_3, which may be stacked in order on the outer surface of the semiconductor pattern 142.

For example, the tunnel insulating film 144_1 may include or may be silicon oxide or a high-k material (e.g., aluminum oxide (Al₂O₃), hafnium oxide (HfO₂)) having a higher dielectric constant than the silicon oxide. For example, the charge storage film 144_2 may be silicon nitride. For example, the blocking insulating film 144_3 may include or may be silicon oxide or a high-k material (e.g., aluminum oxide (Al₂O₃), hafnium oxide (HfO₂)) having a higher dielectric constant than the silicon oxide.

In some aspects, the channel structure CH may further include the filling insulating layer 140. The filling insulating layer 140 may be formed to fill the inside of the cup-shaped semiconductor pattern 142. For example, the filling insulating layer 140 may include or may be an insulating material, for example, silicon oxide, but aspects are not limited thereto.

In some aspects, a channel pad 132 may be disposed on the channel structure CH. The channel pad 132 may be formed and connected to the semiconductor pattern 142. For example, the channel pad 132 may be in the interlayer insulating film 125 and connected to one end of the semiconductor pattern 142. For example, the channel pad 132 may include or may be polysilicon doped with impurities, but aspects are not limited thereto.

The first mold structure MS1 may be divided by the word line cutting regions WCF to form a memory cell block (e.g., BLK of FIG. 1). For example, the word line cutting region WCF may include or may be at least one of insulating material, silicon oxide, silicon nitride, or silicon oxynitride, but aspects are not limited thereto.

The bit lines BL may be formed on the first mold structure MS1. The bit lines BL may intersect the word line cutting regions WCF. For example, each of the bit lines BL may extend in the third direction D3. The bit lines BL may be arranged along the second direction D2 and spaced apart from each other.

Each of the bit lines BL may be connected to each of the channel structures CH arranged along the third direction D3. A bit line contact 136 may be formed in the interlayer insulating film 125. The bit line BL may be electrically connected to the channel structure CH through the bit line contact 136 and the channel pad 132.

The word line contact 160 may be disposed on the extended region EXT of the cell substrate 100. The word line contact 160 may extend in the third direction D3 and may be connected to the gate electrode 120. For example, the word line contact 160 may extend through a portion of the first mold structure MS1 and connected to the corresponding gate electrode 120.

The contact spacer 170 may be disposed on a side surface of the word line contact 160. The contact spacer 170 may extend in the third direction D3 along the side surface of the word line contact 160. The contact spacer 170 may surround the word line contact 160. The contact spacer 170 may be an insulating material. For example, the contact spacer 170 may include or may be a silicon oxide-based insulating material.

The word line contact 160 and the contact spacer 170 may extend through a portion of the first mold structure MS1. For example, the word line contact 160 and the contact spacer 170 may extend through one or more of the plurality of gate electrodes 120. The word line contact 160 and the contact spacer 170 may extend through one or more of the plurality of mold insulating layers 110. For example, the word line contact 160 may extend through one or more of the plurality of gate electrodes 120 and through one or more of the plurality of mold insulating layers 110 and electrically connected to a specific gate electrode.

The word line contact 160 may be a conductive material. For example, the gate electrode 120 may include or may be a metal such as tungsten (W), cobalt (Co), nickel (Ni), or a semiconductor material such as silicon, but aspects are not limited thereto.

A word line via 166 may be disposed on the word line contact 160. The word line via 166 may be disposed in the interlayer insulating film 125. The word line contact 160 may be electrically connected to the cell wiring structure 180 through the word line via 166.

The support structure 150 may be disposed on the extended region EXT of the cell substrate 100. The support structure 150 may be disposed around the word line contact 160. For example, four support structures 150 may be disposed around one word line contact 160. However, aspects are not limited to the above. For example, three support structures 150 may be disposed around one word line contact 160. The support structure 150 may support the first mold structure MS1 or the word line contact 160 to prevent the first mold structure MS1 or the word line contact 160 from collapsing or falling.

The support structure 150 may be an insulating material. For example, the support structure 150 may include or may be a silicon oxide-based insulating material. However, aspects are not limited to the above.

The cell wiring structure 180 may be formed on the first mold structure MS1. For example, a first wiring insulating film 182 may be formed on the interlayer insulating film 125, and the cell wiring structure 180 may be formed in the first wiring insulating film 182. The cell wiring structure 180 may be electrically connected to the bit line BL and the word line contact 160. Accordingly, the cell wiring structure 180 may be electrically connected to the channel structure CH and the gate electrode 120. The number, arrangement, etc. of the layers of the illustrated cell wiring structure 180 are merely illustrative, and aspects are not limited thereto.

The peripheral circuit structure PERI may include a peripheral circuit substrate 300, a peripheral circuit element 360, and a peripheral circuit wiring structure 380.

For example, the peripheral circuit substrate 300 may include a semiconductor substrate such as a silicon substrate, a germanium substrate, or a silicon-germanium substrate. Alternatively, the peripheral circuit substrate 300 may also include a silicon-on-insulator (SOI) substrate or a germanium-on-insulator (GOI) substrate, etc.

The peripheral circuit element 360 may be formed on the peripheral circuit substrate 300. The peripheral circuit element 360 may form a peripheral circuit that controls an operation of the semiconductor memory device. For example, the peripheral circuit element 360 may include a logic circuit 1130, a page buffer 1120, a decoder circuit 1110, etc. of FIG. 20. In the present description, the surface of the peripheral circuit substrate 300 on which the peripheral circuit element 360 is disposed may be referred to as a front side of the peripheral circuit substrate 300. Conversely, the surface of the peripheral circuit substrate 300 opposite the front side of the peripheral circuit substrate 300 may be referred to as a back side of the peripheral circuit substrate 300.

For example, the peripheral circuit element 360 may include a transistor, but aspects are not limited thereto. For example, the peripheral circuit element 360 may include not only various active elements such as transistors, but also various passive elements such as capacitors, registers, and inductors.

The peripheral circuit wiring structure 380 may be formed on the peripheral circuit element 360. For example, a second wiring insulating film 340 may be formed on the front side of the peripheral circuit substrate 300, and the peripheral circuit wiring structure 380 may be formed in the second wiring insulating film 340. The peripheral circuit wiring structure 380 may be electrically connected to the peripheral circuit element 360. The number, arrangement, etc. of the layers of the peripheral circuit wiring structure 380 illustrated are merely examples, and aspects are not limited thereto.

In some aspects, the cell structure CELL may be stacked on the peripheral circuit structure PERI. For example, the cell structure CELL may be stacked on the second wiring insulating film 340.

In some aspects, the first surface 100_A of the cell substrate 100 may be opposite the peripheral circuit structure PERI. For example, the front side (i.e., the first surface 100_A) of the cell substrate 100 may be opposite the front side of the peripheral circuit substrate 300.

The semiconductor memory device according to some aspects may have a chip-to-chip (C2C) structure. The C2C structure refers to manufacturing an upper chip including the cell structure (CELL) on a first wafer (e.g., the cell substrate 100), manufacturing a lower chip including the peripheral circuit structure (PERI) on the second wafer (e.g., the peripheral circuit substrate 300) that is different from the first wafer, and connecting the upper and lower chips to each other by a bonding method.

In some aspects, the bonding method may mean a method of electrically connecting a first bonding metal 185 formed on the lowermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu—Cu bonding method. However, this is only an example, and the first bonding metal 185 and the second bonding metal 385 may be formed of various other metals such as aluminum (Al) or tungsten (W).

As the first bonding metal 185 and the second bonding metal 385 are bonded to each other, the cell wiring structure 180 may be connected to the peripheral circuit wiring structure 380. Accordingly, the bit line BL and/or each of the gate electrodes 120 may be electrically connected to the peripheral circuit element 360.

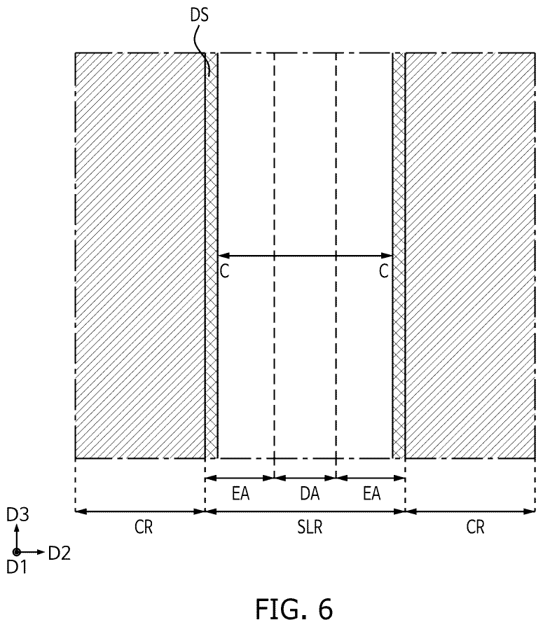

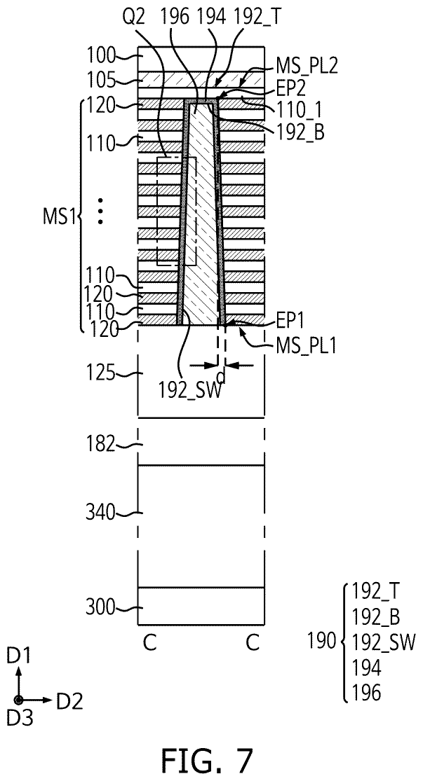

FIG. 6 is a schematic plan view of the scribe lane region SLR of FIG. 1. FIG. 7 is a cross-sectional view taken along line C-C of FIG. 6. FIG. 8 is an enlarged view provided to depict the region Q2 of FIG. 7; For convenience of description, different configurations from those described in FIGS. 1 to 5 will be mainly described.

The scribe lane region SLR may include a dicing region DA for individually separating each of the plurality of chip regions CR, such as separating a first chip region from other chip regions, and an edge region EA between the dicing region DA and the chip region CR. The dicing region DA may include a scribe lane structure 190.

Referring to FIG. 7, the scribe lane structure 190 may include at least one scribe lane trench 192_T formed on the mold structure MS1, a first insulating layer 194 covering a bottom surface 192_B and a sidewall 192_SW of the scribe lane trench 192_T, and a second insulating layer 196 disposed on the first insulating layer 194 and filling the scribe lane trench 192_T.

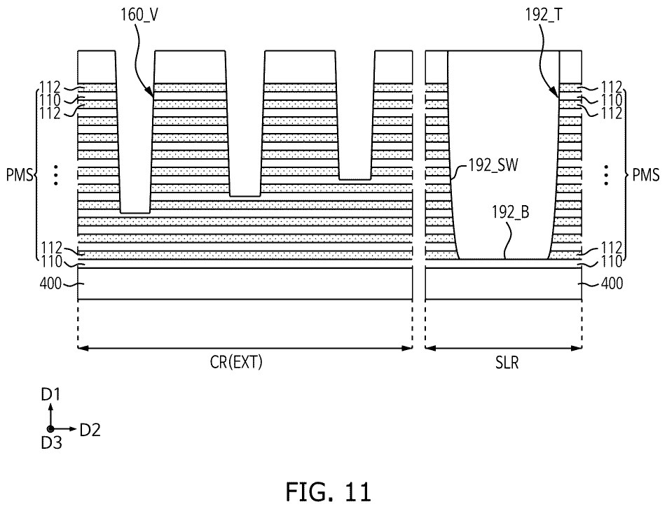

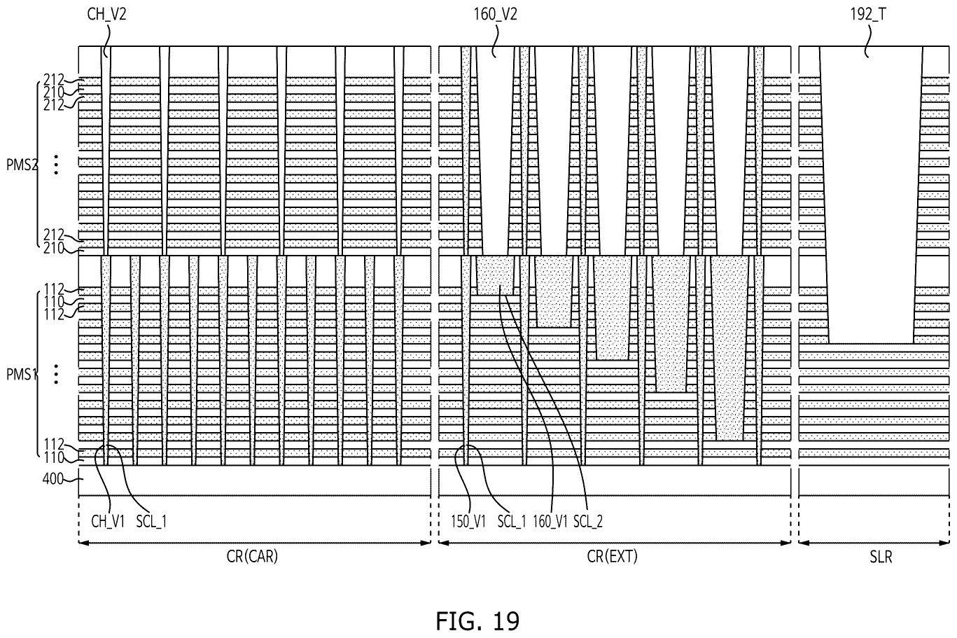

In some aspects, the scribe lane trench 192_T may be formed concurrently with a channel hole (e.g., a second set of channel holes CH_V2 in FIG. 19) of the channel structure CH in the chip region CR and/or a word line contact hole (e.g., a word line contact hole 160_V in FIG. 11 and a second set of word line contact holes 160_V2 in FIG. 19) of the word line contact 160.

The scribe lane trench 192_T may have a tapered shape. For example, the width of the scribe lane trench 192_T may become narrower toward the bottom surface. In some aspects, the scribe lane trench 192_T may be formed concurrently with the channel hole and/or the word line contact hole 160_V in the chip region CR, so that the scribe lane trench 192_T may be formed with a steep slope. For example, from a plan view, a horizontal length d between an edge EP1 of one end of the sidewall 192_SW of the scribe lane trench 192_T and an edge EP2 of the other end opposite to the one end may be 0.5 to 2 micrometers. There may be a distance difference of 1 to 4 micrometers between the width of the bottom surface 192_B of the scribe lane trench 192_T and the width of its upper surface. In the process of individually forming the scribe lane trench, a horizontal length between the edge of one end and the edge of the other end of the scribe lane trench may be 10 to 15 micrometers.

In some aspects, the scribe lane trench 192_T may extend from a first surface MS_PL1 of the mold structure MS1 to a nearest mold insulating layer 110_1 of a second surface MS_PL2 opposite to the first surface MS_PL1. Alternatively, according to another aspect, the scribe lane trench 192_T may extend through from the first surface MS_PL1 of the mold structure MS1 to the second surface MS_PL2 opposite to the first surface MS_PL1.

In some aspects, the sidewall 192_SW of the scribe lane trench 192_T may include a step 192_SWS. The step 192_SWS of the sidewall 192_SW of the scribe lane trench 192_T may be formed symmetrically on both sidewalls.

In some aspects, the first insulating layer 194 may be an undoped silicon. In the semiconductor device manufacturing process, a material of the first insulating layer 194 may be the same material as that of the sacrificial layer filled in the channel hole of the channel structure CH and the word line contact hole 160_V of the word line contact 160. In another aspect, the first insulating layer 194 may include or may be at least one of silicon oxide (SiO), silicon nitride (SiN), silicon oxynitride (SiON), or a low-k material. For example, the low-k material may include or may be fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, or mesoporous silica, or a combination thereof.

The second insulating layer 196 may include or may be at least one of silicon oxide (SiO), silicon nitride (SiN), silicon oxynitride (SiON), or a low-k material. For example, the low-k material may include or may be fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, or mesoporous silica, or a combination thereof, but is not limited thereto.

A dam structure DS may be formed in the edge region EA. The dam structure DS may extend along the scribe lane region SLR to surround the plurality of chip regions CR. When viewed in a plan view, the dam structure DS may have, for example, a ring shape or a closed curve shape. The dam structure DS may include vias extending through the wiring insulating film (e.g., the first wiring insulating film 182), and wirings on the vias.

Although not illustrated, process monitoring devices and test devices may be disposed in the scribe lane region SLR. The process monitoring devices may be monitoring patterns for monitoring semiconductor element manufacturing process, such as various forms of alignment patterns used as alignment reference when performing various semiconductor element manufacturing process, overlay patterns for checking overlaying state between upper and lower patterns, and measurement patterns for measuring thickness and line width of the patterns. The test devices may include test device groups having substantially the same structure as semiconductor integrated circuits in order to evaluate electrical characteristics of semiconductor integrated circuits formed in the plurality of chip regions CR.

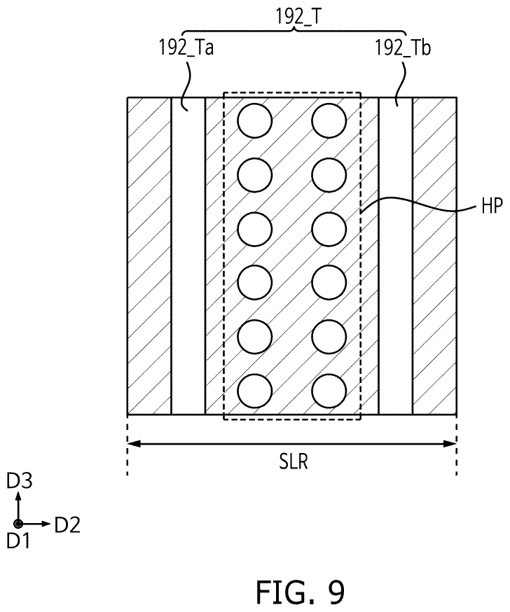

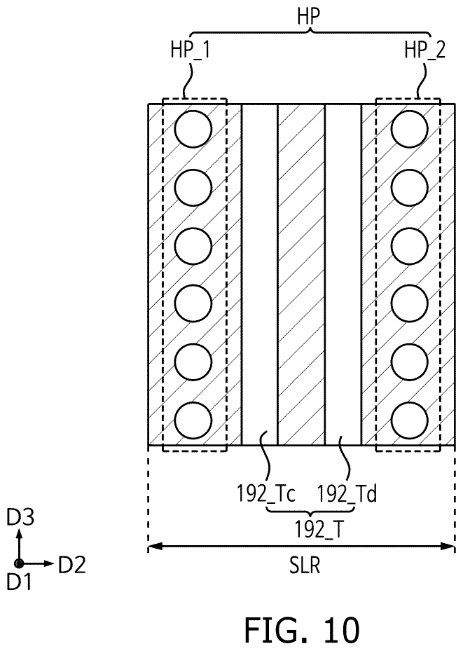

FIGS. 9 and 10 are diagrams provided to depict the scribe lane region SLR according to some aspects.

The scribe lane region SLR may include a plurality of scribe lane trenches 192 and a plurality of hole pattern arrays HP. The hole pattern array HP may include a hole pattern extending through a portion of the mold structure MS in the first direction D1.

For example, referring to FIG. 9, a scribe lane trench 192_T may include a first scribe lane trench 192_Ta and a second scribe lane trench 192_Tb spaced apart from the first scribe lane trench 192_Ta in the second direction D2. In this case, a hole pattern array HP may be disposed between the first scribe lane trench 192_Ta and the second scribe lane trench 192_Tb.

In another example, a hole pattern array HP may include a first hole pattern array HP_1 and a second hole pattern array HP_2 spaced apart from the first hole pattern array HP_1 in the second direction D2. In this case, a scribe lane trench 192_T may be disposed between the first hole pattern array HP_1 and the second hole pattern array HP_2. Referring to FIG. 10, a third scribe lane trench 192_Tc and a fourth scribe lane trench 192_Td may be disposed between the first hole pattern array HP_1 and the second hole pattern array HP_2. Alternatively, one of the third scribe lane trench 192_Tc and the fourth scribe lane trench 192_Td may be disposed between the first hole pattern array HP_1 and the second hole pattern array HP_2.

While FIGS. 9 and 10 illustrate the hole pattern array HP and the scribe lane trench 192_T extending in the third direction D3, it is to be noted that the scribe lane region SLR may also extend in the second direction D2 and the third direction D3 to surround the chip region CR, and therefore, the extending directions of the hole pattern array HP and the scribe lane trench 192_T are not limited to the illustration. The hole pattern array HP and the scribe lane trench 192_T may extend in the second direction D2.

According to example methods, provided is a method of manufacturing a semiconductor memory device that includes a providing a substrate 100 including a first chip region CR, and a scribe lane region SLR surrounding the first chip region CR, providing a mold MS1 including a plurality of mold insulating layers 110_1 and a plurality of gate electrodes 120 which are alternately stacked on each other on the substrate 100 in a first direction D1 perpendicular to the substrate 100, providing a channel CH extending through the mold MS1 in the first direction D1, and providing a plurality of word line contacts 160 extending through at least a portion of the mold MS1 in the first direction D1. The scribe lane region SLR may include a scribe lane trench 192_T in the mold MS1, a first insulating layer 194 covering a bottom surface 192_B and a sidewall 192_SW of the scribe lane trench 192_T, and a second insulating layer 196 on the first insulating layer 194 and filling the scribe lane trench 192_T. According to example embodiments, the substrate 100 includes chip regions CR other than the first chip region CR and the method further includes separating along the scribe lane region SLR the first chip region CR from the other chip regions CR.

According to example embodiments, provided is a method of manufacturing a semiconductor memory device may include providing a substrate 100 including a first chip region CR including a cell array region CAR and an extended region EXT, and a scribe lane region SLR surrounding the first chip region CR, providing a mold MS1 including a plurality of mold insulating layers 110_1 and a plurality of gate electrodes 120 which are alternately stacked on each other on the substrate 100 in a first direction D1; providing a channel CH in the cell array region CAR extending through the mold MS1 in the first direction D1, providing a plurality of word line contacts 160 in the extended region EXT. The plurality of word line contacts 160 may extend through at least a portion of the mold MS1 in the first direction D1, and providing an insulative support 150 disposed around each word line contact 160 of the plurality of word line contacts 160 in the extended region EXT and extending through at least a portion of the mold MS1 in the first direction D1. The plurality of word line contacts 160 may include word line contacts 160 through one or more gate electrode 120 of the plurality of gate electrodes 120, and the scribe lane region SLR may include a scribe lane trench 192_T in the mold MS1, a first insulating layer 194 covering a bottom surface 192_B and a sidewall 192_SW of the scribe lane trench 192_T, and a second insulating layer 196 on the first insulating layer 194 and filling the scribe lane trench 192_T. According to example embodiments, the substrate 100 includes chip regions CR other than the first chip region CR and the method further includes separating along the scribe lane region SLR the first chip region CR from the other chip regions CR.

Also provided are semiconductor memory devices manufactured by the methods provided herein.

FIGS. 11 to 13 are diagrams showing intermediate stages, provided to show a method of manufacturing a semiconductor memory device according to some aspects.

Referring to FIG. 11, a pre-mold structure PMS may be formed on a pre-substrate 400. The pre-mold structure PMS may include the plurality of mold insulating layers 110 and mold sacrificial layers 112 which are alternately stacked on each other. The pre-substrate 400 may include a chip region CR including a cell array region CAR and an extended region EXT, and a scribe lane region SLR surrounding the chip region CR.

The pre-mold structure PMS may be patterned to form the word line contact hole 160_V and the scribe lane trench 192_T. For example, a plurality of word line contact holes 160_V extending through the pre-mold structure PMS in the first direction D1 may be formed in the extended region EXT. In addition, the scribe lane trench 192_T may be formed on the pre-mold structure PMS in the scribe lane region SLR. In this case, the plurality of word line contact holes 160_V and the plurality of scribe lane trenches 192_T may be formed concurrently.

In some aspects, the plurality of scribe lane trenches 192 and the plurality of hole pattern arrays HP described with reference to FIGS. 9 and 10 may be formed in the scribe lane region SLR.

In some aspects, bottom surfaces of the word line contact hole 160_V and the scribe lane trench 192_T may expose the mold insulating layer 110. It is to be noted that the present invention is not limited to the above, and the bottom surfaces of the word line contact hole 160_V and the scribe lane trench 192_T may expose the mold sacrificial layer 112. In some aspects, the bottom surfaces of the scribe lane trench 192_T may expose the mold insulating layer 110 that is closest to the outside of the pre-mold structure PMS. However, aspects are not limited to the above.

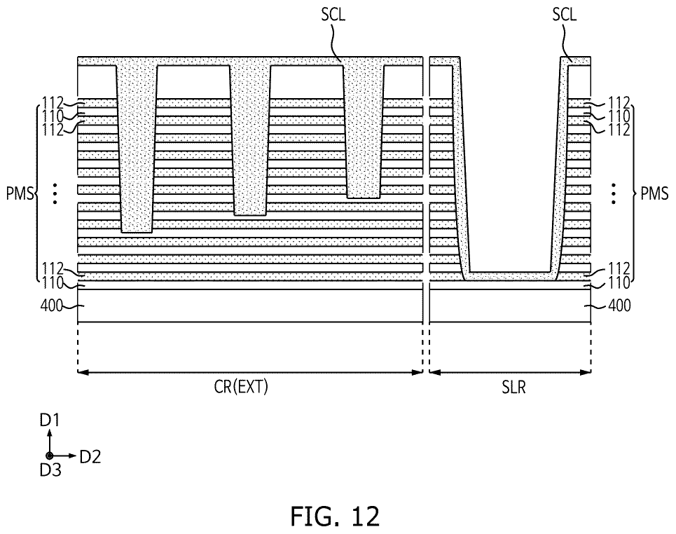

Referring to FIG. 12, a sacrificial layer SCL may be formed in the word line contact hole 160_V, and on the bottom surface 192_B and the sidewall 192_SW of the scribe lane trench 192_T. The sacrificial layer SCL may be undoped silicon, silicon oxide, or silicon nitride. However, aspects are not limited thereto.

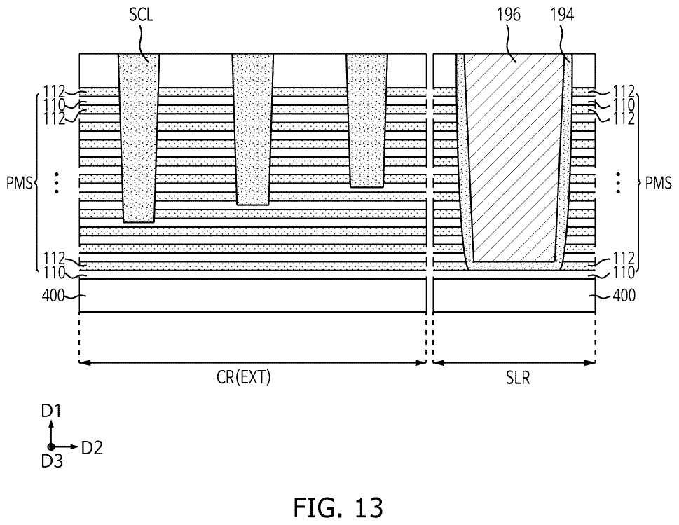

Referring to FIG. 13, insulating material may be filled in the sacrificial layer SCL formed on the bottom surface 192_B and the sidewall 192_SW of the scribe lane trench 192_T. The sacrificial layer SCL formed on the pre-mold structure PMS may be removed to form the first insulating layer 194 covering the bottom surface 192_B and the sidewall 192_SW of the scribe lane trench 192_T. In addition, the insulating material formed on the pre-mold structure PMS may be removed to form the second insulating layer 196 filling the scribe lane trench 192_T. Specifically, the insulating material formed on the pre-mold structure PMS may be removed to a vertical level substantially the same as an upper surface of the pre-mold structure PMS so as to form the second insulating layer 196. The sacrificial layer SCL formed on the pre-mold structure PMS may be removed to a vertical level substantially the same as an upper surface of the second insulating layer 196 so as to form the first insulating layer 194. In this embodiment, the vertical level of the upper surface of the second insulating layer 196 may be used as a reference for stopping the planarization process.

The plurality of mold sacrificial layers 112 may be removed to form the plurality of gate electrodes 120, and the plurality of word line contacts 160 may be formed in the plurality of word line contact holes 160_V by removing the sacrificial layers SCL formed in the plurality of word line contact holes 160_V. For example, the sacrificial layer SCL and the plurality of mold sacrificial layers 112 inside the word line contact hole 160_V may be removed, and the gate electrode may be formed between the plurality of mold insulating layers 110. In addition, a word line contact 160 and a contact spacer 170 may be formed in the word line contact hole 160_V. For example, the contact spacer 170 may be conformally formed along a sidewall of the word line contact hole 160_V, and the word line contact 160 may be formed on the contact spacer 170.

In some aspects, a plurality of word line contacts 160 may include a word line contact extending through one or more gate electrode of the plurality of gate electrodes 120. For example, a first word line contact to contact a first gate electrode of the plurality of gate electrodes 120 may be formed. In addition, a second word line contact that extends through the first gate electrode and contacts a second gate electrode adjacent to the first gate electrode may be formed. The first gate electrode and the second gate electrode may be adjacent to one another, without being in contact with one another, e.g. by having a mold insulating layer therebetween. When the first gate electrode and the second gate electrode are adjacent, they may be for example, the closest gate electrodes 120 to one another. For example, the plurality of word line contacts 160, except for the word line contact in contact with the gate electrode closest to one side of the mold structure MS, may extend through one or more gate electrodes.

As illustrated in FIG. 4, the word line via 166 and the cell wiring structure 180 may be formed on the word line contact 160, and the common source plate 105 and the cell substrate 100 may be formed on the mold structure MS, such that the cell structure CELL may be formed. The cell structure CELL may be bonded to the peripheral structure PERI. As a result, the semiconductor memory device as described herein with reference to FIGS. 1 to 10 may be provided.

FIGS. 11 to 13 illustrate an aspect in which the word line contact hole 160_V in the extended region EXT and the scribe lane trench 192_T in the scribe lane region SLR are formed concurrently, but the aspects are not limited thereto. For example, the channel hole in the cell array region CAR, the word line contact hole 160_V in the extended region EXT, and the scribe lane trench 192_T in the scribe lane region SLR may be formed concurrently. In this aspect, in addition to the method described herein with reference to FIGS. 11 to 13, a channel hole extending through the pre-mold structure PMS in the first direction D1 may be formed in the cell array region CAR, and the channel structure (e.g., the channel structure CH of FIG. 3) may be formed in the channel hole.

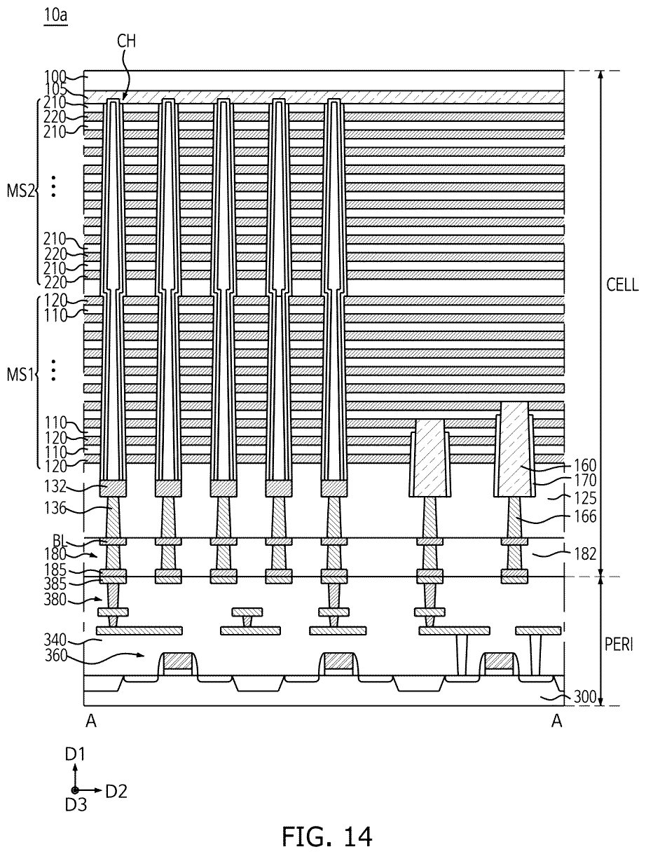

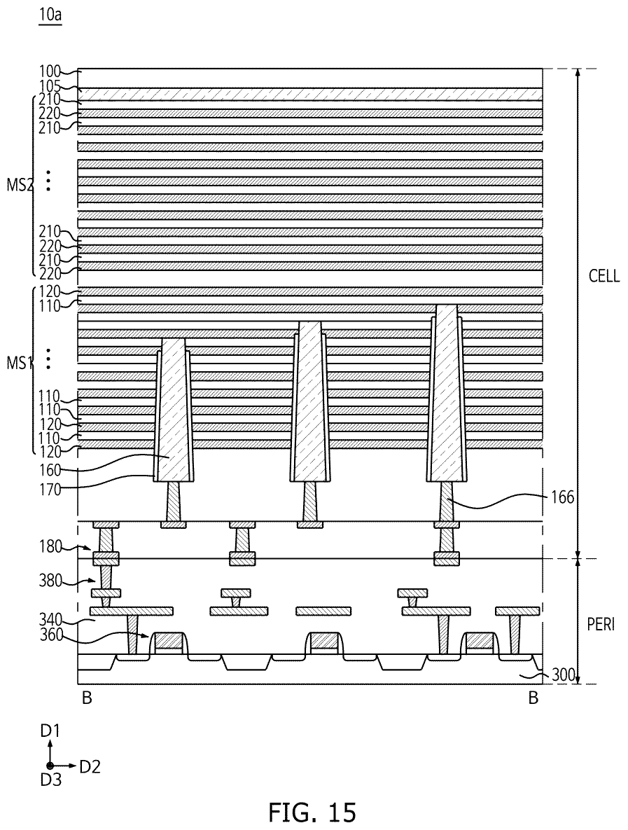

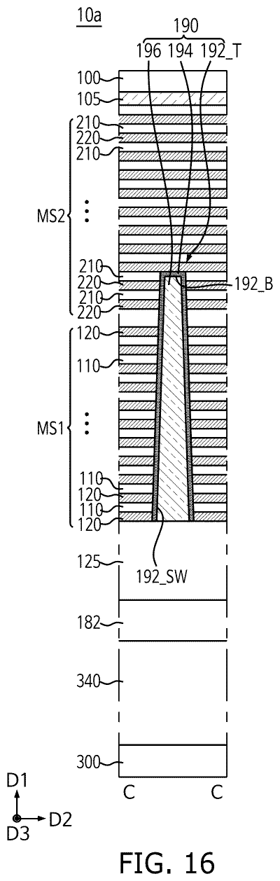

FIGS. 14 to 16 are diagrams provided to depict a semiconductor memory device according to some aspects. For reference, FIG. 14 may correspond to a cross-sectional view taken along line A-A of FIG. 2, and FIG. 15 may correspond to a cross-sectional view taken along line B-B of FIG. 2. In addition, FIG. 16 may correspond to a cross-sectional view taken along line C-C of FIG. 6. A semiconductor memory device 10a of FIGS. 14 to 16 may be substantially the same as the semiconductor memory device 10 described herein with reference to FIGS. 1 to 10, except that a second mold structure (also referred to herein as a “second mold”) MS2 and the first mold structure MS1 are sequentially stacked on the cell substrate 100. According to example embodiments, the substrate is part of a “wafer”. Embodiments of the invention may include separating the semiconductor memory device from the wafer. For convenience of description, different configurations from those described in FIGS. 1 to 10 will be mainly described.

Referring to FIGS. 14 to 16, in the semiconductor memory device according to some aspects, the second mold structure MS2 and the first mold structure MS1 may be stacked in order on the cell substrate 100. The second mold structure MS2 may be disposed on the chip region CR and the scribe lane region SLR of the cell substrate 100.

The second mold structure MS2 may include a plurality of mold insulating layers 210 and a plurality of gate electrodes 220 alternately stacked in the first direction D1. Each of the mold insulating layers 210 and each of the gate electrodes 220 may be layered extending parallel to a surface of the cell substrate 100 (e.g., an upper surface or a lower surface of the cell substrate 100). The gate electrodes 220 may be stacked in order on the common source plate 105 and spaced apart from each other by the mold insulating layers 210.

The first mold structure MS1 may be disposed on the second mold structure MS2. The first mold structure MS1 may include a plurality of mold insulating layers 110 and a plurality of gate electrodes 120 alternately stacked in the first direction D1. A cell insulating layer may be disposed between the first mold structure MS1 and the second mold structure MS2. The cell insulating layer may cover a lower surface of the second mold structure MS2. The first mold structure MS1 may be formed on the cell insulating layer.

Referring to FIG. 14, the channel structure CH may extend in the first direction D1 and may extend through the first mold structure MS1 and the second mold structure MS2. The channel structure CH may have a bent portion between the first mold structure MS1 and the second mold structure MS2.

Referring to FIGS. 15 and 16, the word line contact 160 may extend in the first direction D1 and through the first mold structure MS1 and the second mold structure MS2. The plurality of word line contacts 160 may be electrically connected to the gate electrode 120 of the first mold structure MS1 and the gate electrode 220 of the second mold structure MS2. For example, the word line contact 160 connected to the gate electrode 120 of the first mold structure MS1 may extend through a portion of the first mold structure MS1. The word line contact 160 connected to the gate electrode 120 of the second mold structure MS2 may extend through the first mold structure MS1 and then a portion of the second mold structure MS2.

Although FIGS. 14 to 16 illustrate that the number of mold structures MS1 and MS2 is two, aspects are not limited thereto. For example, the number of the mold structures MS1 and MS2 may be three or four or more.

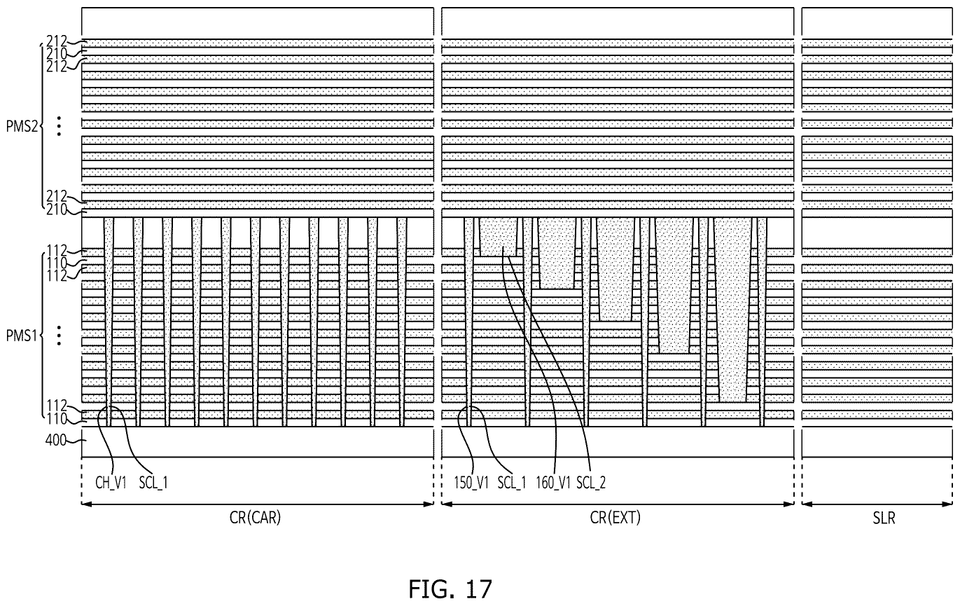

FIGS. 17 to 19 are diagrams showing intermediate stages, provided to depict a method of manufacturing a semiconductor memory device according to some aspects.

Referring to FIG. 17, a second pre-mold structure PMS2 may be stacked on a first pre-mold structure PMS1. In the first pre-mold structure PMS1, a first set of channel holes CH_V1 extending through the first pre-mold structure PMS1 in the first direction D1 in the cell array region CAR may be formed, and a first sacrificial layer SCL_1 may be formed in the channel hole CH_V1. In addition, the first pre-mold structure PMS1 may include, in the extended region EXT, a first set of support structure holes 150_V1 extending through the first pre-mold structure PMS1 in the first direction D1, and the first sacrificial layer SCL_1 formed in the first set of support structure holes 150_V1. In addition, the first pre-mold structure PMS1 may include, in the extended region EXT, a second sacrificial layer SCL_2 formed in the first set of word line contact holes 160_V1 extending through the first pre-mold structure PMS1 in the first direction D1. The first sacrificial layer SCL_1 and the second sacrificial layer SCL_2 may each separately be undoped silicon, silicon oxide, or silicon nitride. However, aspects are not limited to the above. The second pre-mold structure PMS2 may include the plurality of mold insulating layers 210 and a mold sacrificial layer 212 which are alternately stacked on each other.

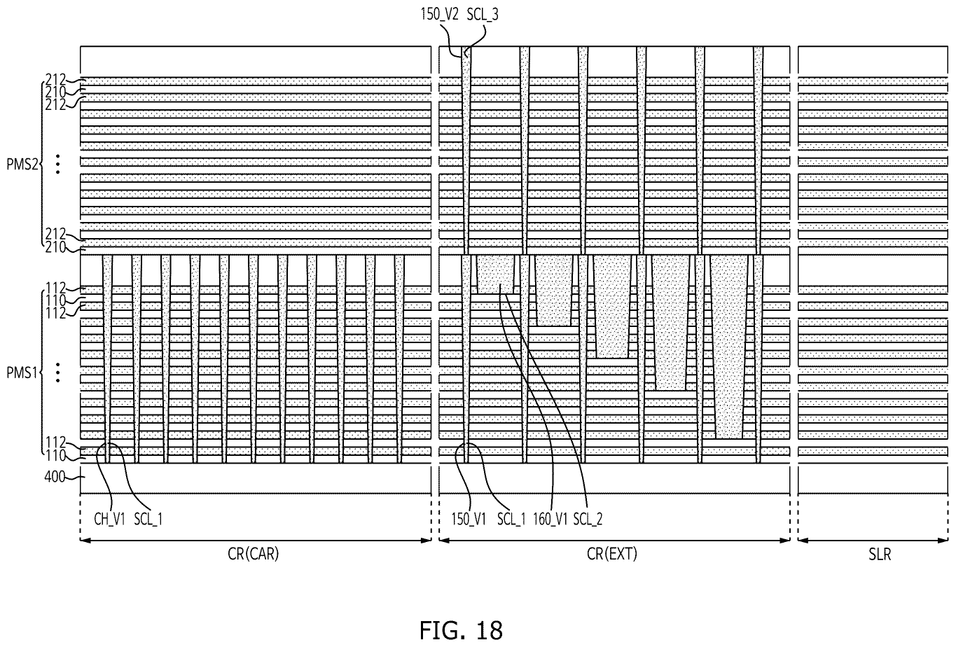

Referring to FIG. 18, the second pre-mold structure PMS2 may be patterned to form a second set of support structure holes 150_V2. For example, the second set of support structure holes 150_V2 extending through the second pre-mold structure PMS2 in the first direction D1 may be formed in the extended region EXT. The second set of support structure holes 150_V2 may be connected to the first set of support structure holes 150_V1 of the first pre-mold structure PMS1. A third sacrificial layer SCL_3 may be formed in the second set of support structure holes 150_V2. The third sacrificial layer SCL_3 may be connected to the first sacrificial layer SCL_1 formed in the first set of support structure holes 150_V1. The third sacrificial layer SCL_3 may be undoped silicon, silicon oxide, or silicon nitride. However, aspects are not limited to the above.

Referring to FIG. 19, the second set of channel holes CH_V2, the second set of word line contact holes 160_V2, and the scribe lane trench 192_T may be formed concurrently by patterning the second pre-mold structure PMS2. For example, the second set of channel holes CH_V2 extending through the second pre-mold structure PMS2 in the first direction D1 may be formed in the cell array region CAR. In addition, the second set of word line contact holes 160_V2 extending through the second pre-mold structure PMS2 in the first direction D1 may be formed in the extended region EXT. In addition, the scribe lane trench 192_T extending through the second pre-mold structure PMS2 in the first direction D1 may be formed in the scribe lane region SLR. In some aspects, the scribe lane trench 192_T may extend through the first mold structure MS1 to a portion of the second mold structure MS2. However, the aspects are not limited thereto, and the scribe lane trench 192_T may extend to a portion of the first mold structure MS1, or extend through the entire second mold structure MS2, for example, extend up to an upper surface of the pre-substrate 400.

In some aspects, the plurality of scribe lane trenches 192 and the plurality of hole pattern arrays HP described with reference to FIGS. 9 and 10 may be formed in the scribe lane region SLR.

Because the second set of channel holes CH_V2, the second set of word line contact holes 160_V2, and the scribe lane trench 192_T are formed concurrently, the scribe lane trench 192_T may be formed more deeply. This may be due to the minimum line width (critical dimension) of the sacrificial layer pattern, which is different from when the scribe lane trenches are formed individually. In addition, by forming the scribe lane trench 192_T concurrently, a proportion of the sacrificial layer pattern in the total volume increases, thereby preventing warpage and crack from occurring due to formation of the scribe lane trench 192_T.

The subsequent processes may be the same as or similar to the processes and methods described herein with reference to FIGS. 11 to 13. For example, a fourth sacrificial layer may be formed in the second set of channel holes CH_V2 and the second set of word line contact holes 160_V2, and on the bottom surface and sidewalls of the scribe lane trench 192_T, and the insulating material may be formed on the fourth sacrificial layer. The fourth sacrificial layer and the insulating material on the second pre-mold structure PMS2 may be partially removed to form the first insulating layer (e.g., the first insulating layer 194 of FIG. 13) and the second insulating layer (e.g., the second insulating layer 196 of FIG. 13) in the scribe lane trench 192_T. The gate electrodes 120 and 220 may be formed between the mold insulating layers 110 and 210, and the word line contact 160 and the contact spacer 170 may be formed.

As a result, the semiconductor memory device as described herein with reference to FIGS. 14 to 16 may be provided.

FIG. 20 is a block diagram provided as an example to depict an electronic system according to some aspects.

Referring to FIG. 20, an electronic system 1000 may include a semiconductor memory device 1100 described herein with reference to FIGS. 1 to 10, and 14 to 16 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device, which may include one or a plurality of semiconductor memory devices 1100.

For example, the semiconductor memory device 1100 may be the NAND flash memory device described herein with reference to FIGS. 1 to 10, and 14 to 16. The semiconductor memory device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be modified according to various aspects.

In some example aspects, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on a memory cell transistor selected from among the plurality of memory cell transistors MCT. The decoder circuit 1110 and the page buffer 1120 may be controlled by the logic circuit 1130. The semiconductor memory device 1100 may communicate with the controller 1200 through the input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some aspects, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware, and may control the NAND controller 1220 to access the semiconductor memory device 1100. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a function of communication between the electronic system 1000 and an external host. Upon receiving a control command from the external host through the host interface 1230, the processor 1210 may control the semiconductor memory device 1100 in response to the control command.

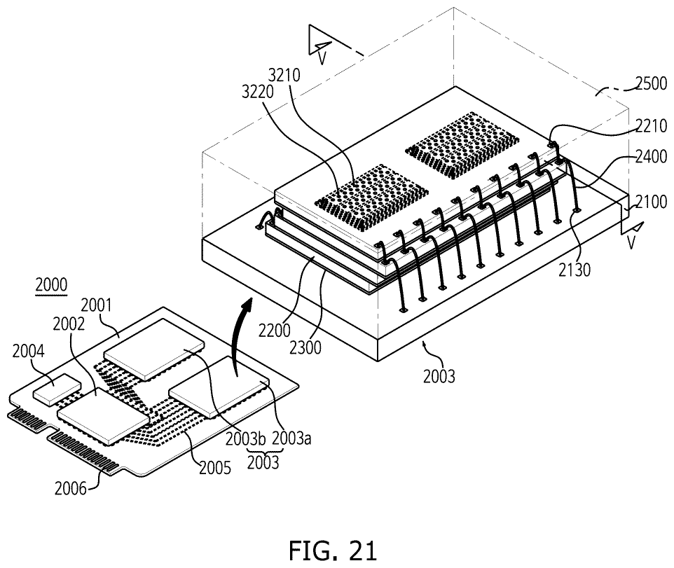

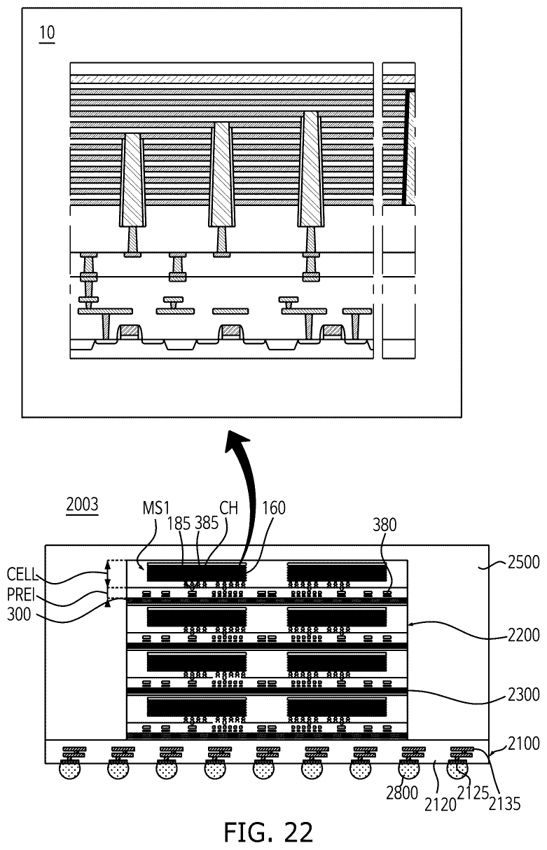

FIG. 21 is an example perspective view illustrating an electronic system including a semiconductor memory device according to some aspects. FIG. 22 is a schematic cross-sectional view taken along line V-V of FIG. 21.

Referring to FIG. 21, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some aspects, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In example aspects, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130, which may be conductive pads. Each of the semiconductor chips 2200 may include an input and output pad 2210. The input and output pad 2210 may correspond to the input and output pad 1101 of FIG. 20. Each of the semiconductor chips 2200 may include metal lines 3210 and channel structures 3220. Each of the semiconductor chips 2200 may include the semiconductor memory device described herein with reference to FIGS. 1 to 10, and 14 to 16.

In some aspects, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some aspects, in each of the first and second semiconductor packages 2003a and 2003b, the semiconductor chips 2200 may be electrically connected to each other through a connection structure including through-electrodes (Through Silicon Via, TSV) instead of the bonding wire type connection structure 2400.

In some aspects, the main controller 2002 and the semiconductor chips 2200 may be included in one package. In some aspects, the main controller 2002 and the semiconductor chips 2200 may be mounted on a separate interposer substrate (not shown) different from the main substrate 2001, and the main controller 2002 and the semiconductor chips 2200 may be connected to each other through wiring formed on the interposer substrate.

In some aspects, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 21.

In the electronic system according to some aspects, each of the semiconductor chips 2200 may include the semiconductor memory device described herein with reference to FIGS. 1 to 10, and 14 to 16. For example, each of the semiconductor chips 2200 may include a peripheral circuit structure PERI and a cell structure CELL stacked on the peripheral circuit structure PERI. The cell structure CELL may include a cell array region CAR, an extended region EXT, and a scribe lane region SLR. For example, the peripheral circuit structure PERI may include the peripheral circuit substrate 300 and the peripheral circuit wiring structure 380 described herein with reference to FIGS. 1 to 10, and 14 to 16. In addition, for example, the cell structure CELL may include the cell substrate 100, the first mold structure MS1, the channel structure CH, the bit line BL, the word line contact 160, the contact spacer 170, and the scribe lane structure 190 described herein with reference to FIGS. 1 to 10, and 14 to 16. The peripheral circuit structure PERI and the cell structure CELL may be bonded to each other through the first bonding metal 185 and the second bonding metal 385.

Although certain aspects of the present invention have been described with reference to the accompanying drawings, those of ordinary skill in the art to which the present invention pertains will understand that the present invention is not limited thereto and may be implemented in other specific forms without changing its technical idea or essential features. Various changes and modifications can be made within the equivalent scope of the technical idea of the present invention by those of ordinary skill in the art. Therefore, it should be understood that the embodiments described herein are illustrative and non-limiting in all respects.

What is claimed is:

1. A method of manufacturing a semiconductor memory device, comprising:
providing a substrate including a first a chip region, and a scribe lane region surrounding the first chip region;
providing a mold including a plurality of mold insulating layers and a plurality of gate electrodes which are alternately stacked on each other on the substrate in a first direction perpendicular to the substrate;
providing a channel extending through the mold in the first direction; and
providing a plurality of word line contacts extending through at least a portion of the mold in the first direction,
wherein
the scribe lane region includes a scribe lane trench in the mold, a first insulating layer covering a bottom surface and a sidewall of the scribe lane trench, and a second insulating layer on the first insulating layer and filling the scribe lane trench, and
wherein the substrate includes chip regions other than the first chip region and the method further comprises separating along the scribe lane region the first chip region from the other chip regions.

2. The method of manufacturing a semiconductor memory device according to claim 1, wherein a first width of the scribe lane trench at the bottom surface of the scribe lane trench is narrower than a second width of the scribe lane trench at an opposite end of the scribe lane trench from the bottom surface.

3. The method of manufacturing a semiconductor memory device according to claim 2, wherein, from a plan view, a horizontal length between an edge of a first end of the sidewall of the scribe lane trench and an edge of a second end of the sidewall of the scribe lane trench opposite to the first end is 0.5 to 2 micrometers.

4. The method of manufacturing a semiconductor memory device according to claim 1, wherein the sidewall of the scribe lane trench includes a step.

5. The method of manufacturing a semiconductor memory device according to claim 1, wherein the first insulating layer includes undoped silicon.

6. The method of manufacturing a semiconductor memory device according to claim 1, wherein the plurality of word line contacts include a word line contact extending through one or more gate electrodes of the plurality of gate electrodes.

7. The method of manufacturing a semiconductor memory device according to claim 1, further comprising a support disposed around each word line contact of the plurality of word line contacts and extending through at least a portion of the mold in the first direction.

8. The method of manufacturing a semiconductor memory device according to claim 1, wherein the scribe lane trench extends through the mold from a first surface of the mold to a second surface of the mold opposite to the first surface.

9. The method of manufacturing a semiconductor memory device according to claim 1, wherein the scribe lane trench extends through the mold from a first surface of the mold to a mold insulating layer nearest to a second surface of the mold opposite the first surface.

10. The method of manufacturing a semiconductor memory device according to claim 1, wherein the scribe lane region further includes a hole pattern array including a hole pattern extending through a portion of the mold in the first direction.

11. The method of manufacturing a semiconductor memory device according to claim 10, wherein
the scribe lane trench includes a first scribe lane trench, and a second scribe lane trench spaced apart from the first scribe lane trench in a second direction perpendicular to the first direction, and
the hole pattern array is disposed between the first scribe lane trench and the second scribe lane trench.

12. The method of manufacturing a semiconductor memory device according to claim 10, wherein
the hole pattern array includes a first hole pattern array and a second hole pattern array spaced apart from the first hole pattern array in a second direction perpendicular to the first direction, and
the scribe lane trench is disposed between the first hole pattern array and the second hole pattern array.

13. A method of manufacturing a semiconductor memory device, comprising:
providing a substrate including a first chip region including a cell array region and an extended region, and a scribe lane region surrounding the first chip region;
providing a mold including a plurality of mold insulating layers and a plurality of gate electrodes which are alternately stacked on each other on the substrate in a first direction;
providing a channel in the cell array region extending through the mold in the first direction;
providing a plurality of word line contacts in the extended region, wherein the plurality of word line contacts extend through at least a portion of the mold in the first direction; and
providing an insulative support disposed around each word line contact of the plurality of word line contacts in the extended region and extending through at least a portion of the mold in the first direction, wherein
the plurality of word line contacts include word line contacts extending through one or more gate electrode of the plurality of gate electrodes, and
the scribe lane region includes a scribe lane trench in the mold, a first insulating layer covering a bottom surface and a sidewall of the scribe lane trench, and a second insulating layer on the first insulating layer and filling the scribe lane trench, and
wherein the substrate includes chip regions other than the first chip region and the method further comprises separating along the scribe lane region the first chip region from the other chip regions.

14. A method of manufacturing a semiconductor memory device, comprising:
alternately stacking a plurality of mold insulating layers and a plurality of mold sacrificial layers on a substrate in a first direction to form a pre-mold structure, wherein the substrate includes a chip region including a cell array region and an extended region, and a scribe lane region surrounding the chip region;
forming a plurality of word line contact holes in the extended region, wherein the plurality of word line contact holes extend through at least a portion of the pre-mold structure in the first direction;
forming a scribe lane trench on the pre-mold structure in the scribe lane region; and
forming a sacrificial layer in the plurality of word line contact holes and on a bottom surface and a sidewall of the scribe lane trench, wherein
the plurality of word line contact holes and the scribe lane trench are formed concurrently.

15. The method according to claim 14, further comprising:
forming a second insulating layer to fill the scribe lane trench on a first insulating layer, on the sacrificial layer on the bottom surface and the sidewall of the scribe lane trench;
removing the plurality of mold sacrificial layers and the sacrificial layer formed in the plurality of word line contact holes;
forming a plurality of gate electrodes between the plurality of mold insulating layers; and
forming a plurality of word line contacts in the plurality of word line contact holes.

16. The method according to claim 15, wherein
the forming the plurality of word line contacts in the plurality of word line contact holes further includes:
forming a first word line contact that contacts a first gate electrode of the plurality of gate electrodes; and
forming a second word line contact that extends through the first gate electrode and contacts a second gate electrode adjacent to the first gate electrode.

17. The method according to claim 14, further comprising:
forming a channel hole in the cell array region, wherein the channel hole extends through the pre-mold structure in the first direction; and
forming a channel in the channel hole,
wherein the channel hole, the plurality of word line contact holes, and the scribe lane trench are formed concurrently.

18. The method according to claim 14, wherein a first width of the scribe lane trench at the bottom surface of the scribe lane trench is narrower than a second width of the scribe lane trench at an opposite end of the scribe lane trench from the bottom surface.

19. The method according to claim 18, wherein, from a plan view, a horizontal length between an edge of an uppermost first end of the sidewall of the scribe lane trench and an edge of a lowermost second end of the sidewall of the scribe lane trench is 0.5 to 2 micrometers.

20. The method according to claim 14, wherein the sidewall of the scribe lane trench includes a step.
